(19) United States
(12) Patent Application Publication
(10) Pub. No.: US 2008/0135956 A1
(43) Pub. Date: Jun. 12, 2008

(54) Articles and assembly for magnetically directed self assembly and methods of manufacture

(75) Inventors: William Hullinger Huber, Scotia, NY (US); Francis Johnson, Clifton Park, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/637,668

(22) Filed: Dec. 12, 2006

(51) Int. Cl. H01L 29/82; B32B 3/00; B05D 5/12

(52) U.S. Cl. 257/421; 428/209; 427/123; 257/E29.323

(57) ABSTRACT

A functional block for assembly includes at least one element and a magnetic film attached to the element and having a magnetic remanence (M_{R}/M_{S}) of less than about 0.2, having a coercive field (H_{c}) of less than about 100 Oersteds (100 Oe) and having a permeability (μ) of greater than about two (2). At least one element is selected from the group consisting of a semiconductor device, a passive element, a photonic bandgap element, a luminescent material, a sensor, a micro-electrical mechanical system (MEMS), an energy harvesting device and combinations thereof. An article for assembly includes a substrate and a patterned magnetic film disposed on the substrate and defining at least one receptor site. The patterned magnetic film is magnetized primarily in a longitudinal direction and is characterized by a BH product of greater than about 1 megaGauss Oe.

### BACKGROUND

The invention relates generally to the assembly of components onto a surface, and more particularly, to the assembly of building blocks onto a substrate for electronic circuit fabrication, sensors, energy conversion, photonics and other applications.

There is a concerted effort to develop large area, high performance electronics for applications such as medical imaging, nondestructive testing, industrial inspection, security, displays, lighting and photovoltaics, among others. Two approaches are typically employed. For systems involving large numbers of active elements (for example, transistors) clustered at a relatively small number of locations, a “pick and place” technique is typically employed, for which the active elements are fabricated, for example using single crystal semiconductor wafers, and singulated (separated) into relatively large components (for example, on the order of 5 mm) comprising multiple active elements. The components are sequentially placed on a printed circuit board (PCB). Typically, the components are sequentially positioned on the PCB using robotics. Because the pick and place approach can leverage high performance active elements, it is suitable for fabricating high performance electronics.

A key limitation of the pick and place approach is that the components must be serially placed on the PCB. Therefore, as the number of components to be assembled increases, the manufacturing cost increases to the point where costs become prohibitive. In addition, as the component size decreases, it becomes increasingly difficult to manipulate and position the components using robotics. Accordingly, this technique is ill-suited for the manufacture of low density, distributed electronics, such as flat panel displays or digital x-ray detectors. Instead, a wide-area, thin film transistor (TFT) based approach is typically employed to manufacture low density, distributed electronics. Typically, the TFTs comprise amorphous silicon (a-Si) TFTs fabricated on large glass substrates. Although a-Si TFTs have been successfully fabricated over large areas (e.g. liquid crystal displays), the transistor performance is relatively low and therefore limited to simple switches. In addition, with this process, the unit cost of a large area electronic circuit necessarily scales with the size of the circuit.

Another approach is to substitute a higher mobility semiconducting material, such as polysilicon, cadmium selenide (CdSe), cadmium sulfide (CdS) or germanium (Ge), for a-Si to form higher mobility TFTs. While TFTs formed using these higher mobility materials have been shown to be useful for small-scale circuits, their transistor characteristics are inferior to single crystal transistors, and thus circuits made from these materials are inherently inferior to their single crystal counterparts. As with a-Si, the unit cost of a large area electronic circuit necessarily scales with the size of the circuit, for this process.

A number of approaches have been developed to overcome these problems. U.S. Pat. No. 6,780,696, to Schatz, entitled “Method and apparatus for self-assembly of functional blocks on a substrate facilitated by electrode pairs,” employs a fluidic self-assembly process to assemble trapezoidal shaped functional blocks dispersed in a solution onto a substrate having corresponding trapezoidal indentations. In one embodiment, electrodes are coupled to the substrate to form an electric field. This embodiment further forms high-dielectric constant materials on the blocks, such that the blocks are attracted to higher electric field regions and are thus guided to the trapezoidal indents. In another embodiment, the block is formed of a low magnetic permeability material, and a high magnetic permeability layer is coupled to the bottom surface of the block. A static magnetic field is generated at a receptor site by covering the receptor site with a permanent magnet having a north and a south pole aligned such that the static magnetic field is aligned parallel to the surface of the receptor site. In another embodiment, a high magnetic permeability material 1322 is disposed on a substrate, and an external magnetic field is applied parallel to the substrate to attract the functional blocks. A drawback of both magnetic techniques disclosed in Schatz is that the components will tend to agglomerate in solution due to the high remanent magnetization typical of high permeability magnetic materials. Typically prepared high permeability magnetic films, such as vapor deposited Ni₈₀Fe₂₀, have a large remanent magnetization (M_{R}/Mₛ) due to alignment of the easy axis of magnetization parallel to the film plane as shown for example in FIG. 14. Because of the large remanent magnetization, components that pass near a binding site but do not bind will be magnetized. When a magnetized component encounters another similarly magnetized component in solution, the two will agglomerate to minimize their magnetic energy. Schatz does not recognize or address this issue. Nor does Schatz teach or suggest a method for producing magnetic films that overcome this issue.

U.S. Pat. No. 3,439,416, to Yando, entitled “Method and apparatus for fabricating an array of discrete elements,” forms pairs of magnets in a laminated base. Magnetic coatings, such as iron, are applied to the surface of elements. A multiplicity of elements is placed on the surface of the laminated base, which is then vibrated to move the elements. The magnetic coated surfaces of the elements are attracted to the pole faces of the magnet pairs. This technique suffers from several drawbacks, including severe limitations on the shape, size and distribution of the elements. For example, element width must match the spacing of the magnetic layers in the laminated base and the distribution of the elements is restricted by the parallel lamination geometry. In addition the technique appears to be applicable to relatively large, millimeter sized dimensions, and may not be suitable for smaller, micron-sized elements.

“Programmable assembly of heterogeneous colloidal particle arrays,” Yellen et al., Adv. Mater. 2004, 16, No. 2, January 16, p. 111-115, employs magnetically programmable assembly to form heterogeneous colloidal particle arrays. This approach utilizes micromagnets that are covered with an array of square microwells and which are magnetized parallel to the plane. The substrate is immersed in a bath, and superparamagnetic colloidal beads are injected into the bath. External magnetic fields are applied perpendicular to the plane in a first direction, causing the beads to be attracted to one pole of the micromagnets. The direction of the external magnetic field is then reversed, causing the beads to be attracted to the other pole of the micromagnets. A limitation of this technique is that it requires the application of external magnetic fields and appears to be limited to superparamagnetic spherical beads. Further, the beads would not lend themselves to assembly of cubic or similarly shaped functional blocks, a practical prerequisite for self-assembly of electronic components. Another limitation on this technique is use of microwells to trap the beads. The microwells add additional process steps and therefore would negatively impact yield. In addition, Yellen teaches that the self-assembly yield is highly sensitive to delicate compromise between the field gradient generated by the patterned magnetic films and the applied magnetic field which magnetizes the superparamagnetic beads. In a high-volume manufacturing environment, unavoidable small variations in the patterned magnetic films composition and size will affect the field gradient and therefore perturb the optimum applied field for higher yield self-assembly. Because Yellen et al. specifically teaches the application of a uniform magnetic field over a large number of self-assembly sites, those sites with larger (or smaller) optimum field strengths than the applied field will necessarily have a low self-assembly yield. Thus, when averaged over a large number of panels in a manufacturing environment, Yellen's process will produce a low yield.

It would therefore be desirable to provide systems and methods for fabricating high performance, large area electronics rapidly and inexpensively. It would further be desirable for the improved systems and methods to reduce agglomeration of functional blocks and increase yield.

### BRIEF DESCRIPTION

One aspect of the present invention resides in a functional block for assembly. The functional block includes at least one element and a magnetic film attached to the element and having a magnetic remanence (M_{R}/M_{S}) of less than about 0.2, having a coercive field (H_{c}) of less than about 100 Oersteds (100 Oe) and having a permeability (μ) of greater than about two (2). At least one element is selected from the group consisting of a semiconductor device, a passive element, a photonic bandgap element, a luminescent material, a sensor, a micro-electrical mechanical system (MEMS), an energy harvesting device and combinations thereof.

Another aspect of the present invention resides in an article for assembly. The article includes a substrate and a patterned magnetic film disposed on the substrate and defining at least one receptor site. The patterned magnetic film is magnetized primarily in a longitudinal direction and is characterized by a BH product of greater than about 1 megaGauss Oe.

Yet another aspect of the present invention resides in a method of manufacture comprising forming a magnetic film on a host substrate having an array of elements. The magnetic film has a magnetic remanence (M_{R}/M_{S}) of less than about 0.2, has a coercive field (H_{c}) of less than about 100 Oersteds (100 Oe) and has a permeability (μ) of greater than about 2.

Another aspect of the present invention resides in a method of forming an article for assembly. The method includes disposing a magnetic film on a substrate. The magnetic film is characterized by a BH product of greater than about 1 megaGauss Oe. The method further includes patterning the magnetic film to form at least one receptor site and magnetizing the magnetic film, such that the magnetic film has a longitudinal magnetic anisotropy.

Yet another aspect of the present invention resides in an assembly that includes at least one functional block comprising at least one element selected from the group consisting of a semiconductor device, a passive element, a photonic bandgap element, a luminescent material, a sensor, a micro-electrical mechanical system (MEMS), an energy harvesting device and combinations thereof. The functional block further includes a magnetic film attached to the element and having a magnetic remanence (M_{R}/M_{S}) of less than about 0.2, a coercive field (H_{c}) of less than about 100 Oersteds (100 Oe) and a permeability (μ) of greater than about 2. The assembly further includes an article comprising a substrate with at least one receptor site for assembling a respective one of the at least one functional block.

### DRAWINGS

These and other features, aspects, and advantages of the present invention will become better understood when the following detailed description is read with reference to the accompanying drawings in which like characters represent like parts throughout the drawings, wherein:

FIG. 1 illustrates an exemplary functional block embodiment of the present invention;

FIG. 2 depicts another exemplary functional block embodiment with a patterned magnetic film;

FIG. 3 illustrates an exemplary annular shaped patterned magnetic film for a functional block with a circular electrical contact;

FIG. 4 illustrates an exemplary annular shaped patterned magnetic film for a functional block with an annular shaped electrical contact;

FIG. 5 illustrates an exemplary functional block embodiment of the present invention;

FIG. 6 schematically depicts an exemplary article embodiment of the invention with three exemplary receptor sites for attachment to three exemplary functional blocks;

FIG. 7 schematically depicts an exemplary article embodiment of the invention with a magnetic screening layer;

FIG. 8 depicts an exemplary article embodiment in top view;

FIG. 9 is a top view of an interconnect layer for an article;

FIG. 10 is a side view of the article in FIG. 1;

FIG. 11 schematically depicts an exemplary embodiment of stencil printing of magnetic material on functional blocks;

FIG. 12 schematically depicts an exemplary embodiment with side contacts to functional blocks;

FIG. 13 schematically depicts an exemplary embodiment with side contacts to functional blocks;

FIG. 14 illustrates a typical magnetic response of vapor deposited high permeability Ni₈₀Fe₂₀ films; and

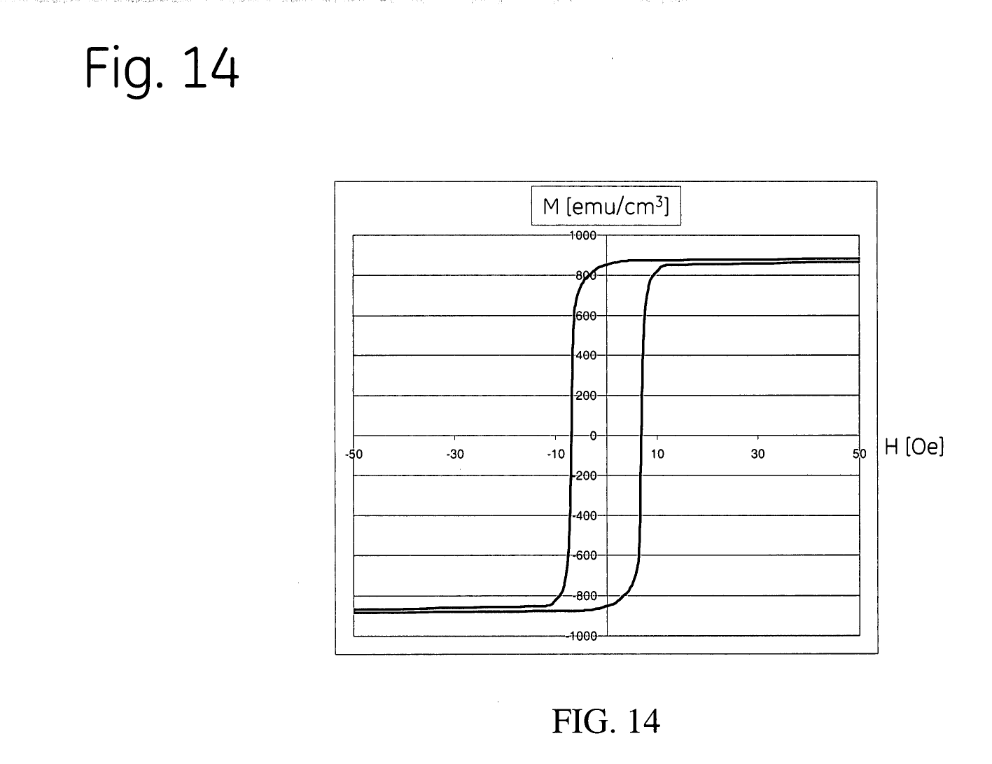

FIG. 15 illustrates a serrated film edge with stray fields contained within the serrated edges.

### DETAILED DESCRIPTION

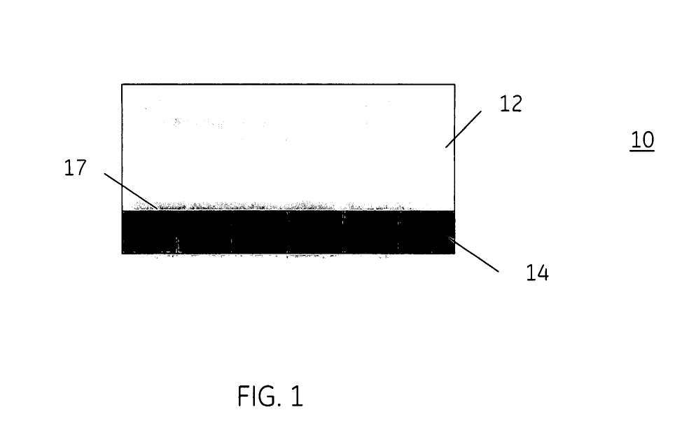

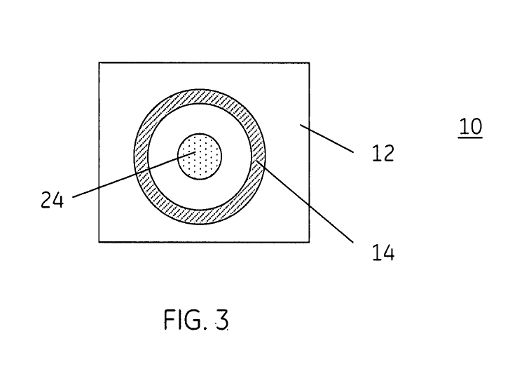

A functional block 10 for assembly is described with reference to FIGS. 1-5. As shown for example in FIG. 1, the functional block 10 includes at least one element 12 and a magnetic film 14 attached to the element 12 and having a magnetic remanence (M_{R}/M_{S}) of less than about 0.2, a coercive field (H_{c}) of less than about 100 Oersteds (100 Oe) and a permeability (μ) of greater than about two (2). As used herein, the term “film” refers to a structure having one or more layers. As used here, the term “attached” should be understood to include magnetic films 14 deposited on or otherwise affixed, either directly or indirectly, to the element 12 (as indicated in FIG. 1, for example), as well as magnetic films 14 deposited on or otherwise affixed to an intermediate layer (not shown), such as SiO₂ or Si₃N₄, formed on the element 12. In other examples, the film 14 is attached indirectly to the element, for example the film is affixed to an electrical contact 24 for the element 12. Electrical contacts are discussed below with reference to FIGS. 3-5. Moreover, the term “attached” also encompasses magnetic films 14 that are partially or fully embedded in the device (not shown). In certain embodiments, the element 12 is formed in a semiconductor layer (also indicated by reference numeral 12). Thus, “attached to the element” means attached to the semiconductor layer, for these embodiments. In other words, a magnetic film 14 need not be affixed to the active portion of element 12 to be “attached to element 12.” Rather, in many configurations, the magnetic film 14 may be affixed to an inactive portion of element 12.

According to more particular embodiments, the magnetic remanence (M_{R}/M_{S}) is less than about 0.1. In other embodiments, the magnetic remanence (M_{R}/M_{S}) is less than about 0.05. In certain embodiments, the magnetic film 14 comprises a superparamagnetic material. A superparamagnetic material has a magnetic remanence (M_{R}/M_{S}) of about 0, for example M_{R}/M_{S}<0.1. Superparamagnetic materials are typically comprised of nanometer-sized magnetic particles embedded in a non-magnetic medium. A magnetic material is considered superparamagnetic if the energy required to flip the magnetization direction within a nanoparticle is comparable to or less than the thermal energy. For example, Fe₃O₄ becomes superparamagnetic at room temperature if the diameter is less than approximately 10 nm. For other materials, the maximum particle size will vary; depending upon the internal magnetic anisotropy. To generate a higher low-field permeability (and therefore a larger binding force), a larger nanoparticle size is preferred. In general, materials with high permeability in bulk possess weak internal magnetic anisotropy. Non-limiting examples of high-permeability materials include Fe₃O₄, γ-Fe₂O₃, Ni₈₀Fe₂₀, NiFe₂O₄, MnFe₂O₄, Ni, Fe and combinations thereof.

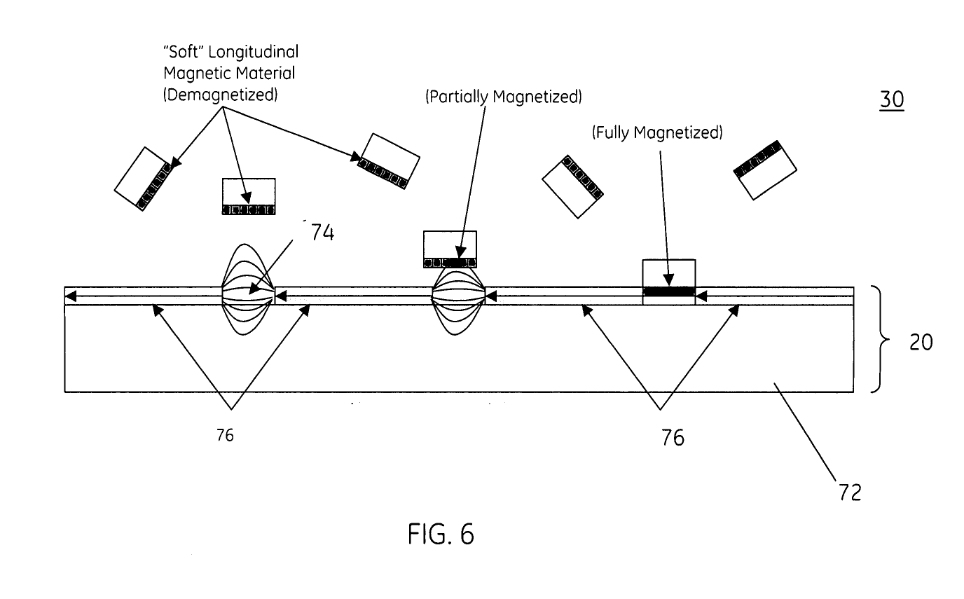

As noted above, the magnetic film 14 has a low-field permeability, μ=B/H, that is high, for example μ≧2. In certain examples, μ≧10, in other examples, μ≧100. Generally, the desired value of the low field permeability μ for the functional blocks will depend upon the strength of the magnetic field generated by the article 20 (discussed below with reference to FIGS. 6-10), which in turn depends in part upon the thickness and material properties of the magnetic portions of the article 20.

The function of the magnetic materials to be employed on the functional blocks is to be susceptible to the static magnetic fields emanating from the poles of the substrate surface. It is a simultaneous requirement that freely floating functional blocks not produce a large enough static magnetic field that may attract other functional blocks. Practically speaking, a susceptible material must have sufficient permeability to enable the functional block to respond to substrate field. Additionally, the functional blocks must have a low enough magnetic remanence to prevent agglomeration while the blocks are substantial distance from the substrate.

Soft magnetic materials can be employed that have high permeabilities and low remanence. Permeability and remanence are extrinsic material properties, meaning that they depend on both the characteristics of the elemental composition as well as the shape, thickness, and microstructure of the magnetic film.

To maximize the permeability of a soft material, the elemental composition of the magnetic material must be chosen to minimize the magnetocrystalline and magnetoelastic anisotropies. The magnetoelastic anisotropy may be minimized by choosing compositions with minimum magnetostrictive coefficients. In one example, a quaternary Ni—Fe—Mo—Cu alloy may be chosen with an elemental composition that lies near the zero crossing of the magnetocrystalline anisotropy and magnetostrictive coefficients. In another example, an amorphous alloy containing Co, Fe, Ni, Si and B may be employed that has no magnetocrystalline anisotropy due its amorphicity and exhibits no magnetostriction due to its electronic structure.

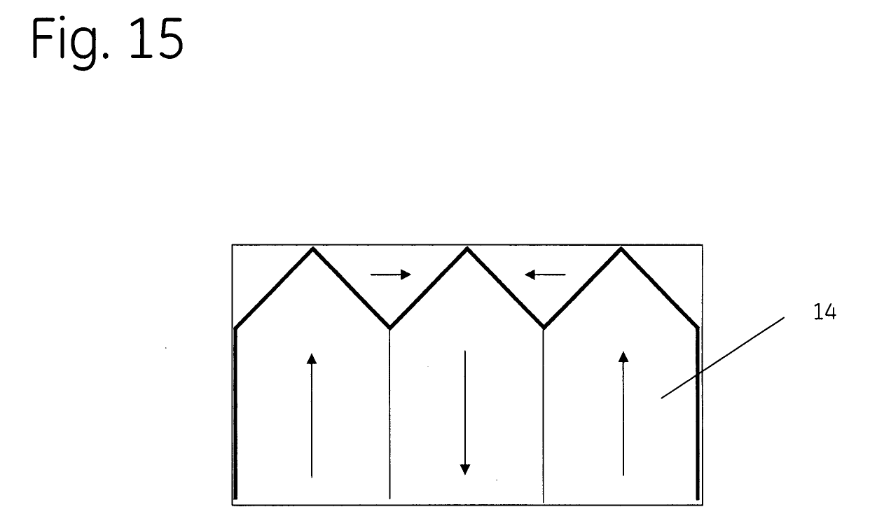

To minimize remanence, the material must return to the demagnetized state upon removal of an external magnetic field. In soft magnetic films this is achieved by controlling the orientation and distribution of magnetic domains within the material. In one example, a magnetic anisotropy may be induced in the material by annealing the film in an external magnetic field. In this example, the vector of the anisotropy easy axis is parallel to externally applied field direction and one component of the vector is substantially in the direction perpendicular to the plane of the film. In this example, the film acquires small, narrowly spaced domains with a minimal amount of stray magnetic field outside the volume of the film, yielding a low remanence. By annealing the magnetic film 14 in a magnetic field normal to the film plane, the easy axis of magnetization is normal to the film plane. As the magnetic field generated by the hard magnetic films 76 is generally in a longitudinal direction, the remanent magnetization of the magnetic film 14 will be low. In another example, such as that illustrated in FIG. 15, the magnetic film comprises at least one surface that is textured to generate a perpendicular anisotropy. As shown for example in FIG. 15, the edge of the magnetic film is serrated, and the wavelength of the serrations is set by the equilibrium domain spacing (the equilibrium spacing may be calculated from the composition and thickness of the film). In this example, the stray fields from the domains emanate from the sides of the serrations and are substantially confined within the serrated edges, producing a low remanence.

Superparamagnetic materials may also be employed that have sufficient permeabilities and zero remanence on the time scale of interest. An exemplary superparamagnetic material comprises small particles or grains of ferromagnetic material embedded in a matrix of non-ferromagnetic material. The magnetic relaxation time of the particles or grains is set by the balance between the anisotropy energy of the material and thermal energy of the environment. Within the relaxation time, the remanence decays to zero. The permeability of superparamagnetic material is determined by the degree to which an external magnetic field biases the balance between the anisotropy and thermal energy. As such, the permeability of a superparamagnetic material is very sensitive to the temperature of the environment.

### EXAMPLE

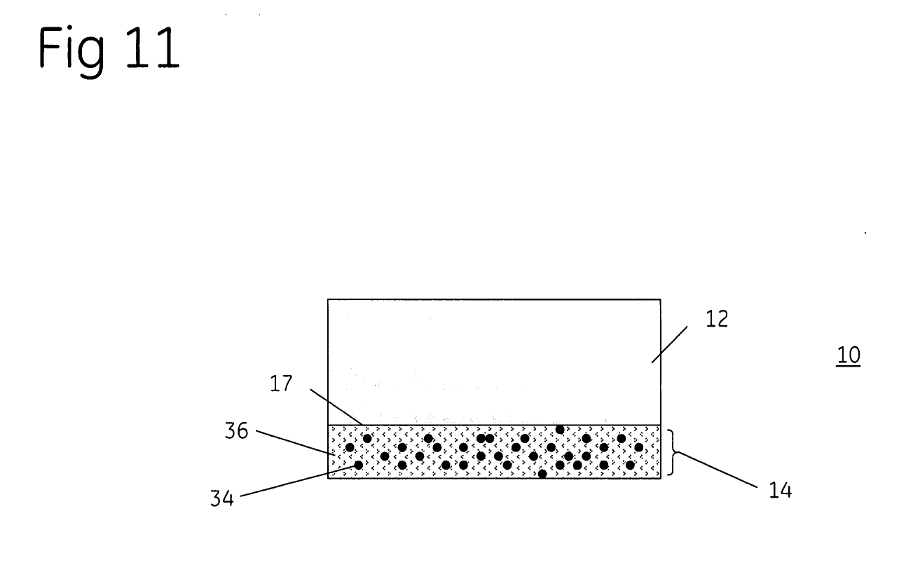

The magnetic film 14 may be fabricated from a variety of different materials using a variety of different techniques. In one non-limiting example illustrated by FIG. 11, the magnetic film 14 comprises superparamagnetic nanoparticles 34 embedded in a polymer binder 36. Non-limiting examples of superparamagnetic nanoparticles 34 include Fe₃O₄, γ-Fe₂O₃, Ni₈₀Fe₂₀, NiFe₂O₄, MnFe₂O₄, MnZn ferrite, NiZn ferrite, Ni, Fe and combinations thereof. As is known in the art, certain magnetic nanoparticles prone to oxidation may be coated with a barrier layer to reduce oxidation. Non-limiting examples of barrier layers (not shown) include Au, Ag, SiO₂, Al₂O₃, TiO₂ and Si₃N₄. Non-limiting examples of polymer binders 36 include thermosetting compounds such as PI-2555 polyimide resin from HD Microsystems and thermoplastics such as nylon. The magnetic film 14 may also contain additional dispersants to reduce particle agglomeration and/or adhesion promoters as is known in the art. The compound can then be applied to the substrate using a variety of different techniques as is known in the art. Non-limiting examples include, spin-coating, stencil printing, screen printing and gravure printing. The polymer binder is then cured using techniques known in the art. Depending upon the application technique, the magnetic film may be further patterned using photolithographic techniques or laser ablation.

In another embodiment, the magnetic film 14 is deposited using conventional thin-film process techniques, non-limiting examples include sputtering, evaporation, electroplating, and chemical vapor deposition. Non-limiting examples of magnetic films include Permalloy® (e.g. Ni₈₀Fe₂₀), Sendust® (FeSiAl alloy) and Fe—Co—B alloys. The film is then annealed in a perpendicular magnetic field to orient the easy axis of magnetization towards the perpendicular direction. By orienting the easy axis away from the film plane, the remnant magnetization for fields applied in the longitudinal direction will be reduced. Thus the amount of block agglomeration in solution will be similarly reduced.

In one example of a superparamagnetic material, nanometer sized particles of magnetic compounds are dispersed in a nonmagnetic matrix. The size of the magnetic particles is controlled to give a relaxation time on the order of seconds. The volume fraction of the particles within the matrix is controlled to prevent interparticle magnetic coupling, which may interfere with the superparamagnetism. In a particular example, the magnetic particles are of the class of ferrite compounds, which include Mn—Zn and Ni—Zn ferrites. In another particular example, the magnetic particles are of the class of compounds known as garnets, which include Yttrium-Iron-Garnet (YIG) and Gadolinium-Gallium-Garnet (GGG). In another particular example, the magnetic particles may be nanoparticles of Fe, Co, or Ni metals, or alloys thereof. In another particular example, the matrix may be a polymer compound. In another example, the matrix may be a non-magnetic oxide.

In another example of a superparamagnetic material, nanometer sized grains of a ferromagnetic material are precipitated from a non-magnetic matrix. The size of the granular precipitates is controlled to give a relaxation time on the order of seconds. The volume fraction of the granular precipitates within the matrix is controlled to prevent interparticle magnetic coupling, which may interfere with the superparamagnetism. In particular example, an Co—Cu alloy film is produced with Cu being the majority constituent. In this example, an annealing process is used to precipitate superparamagnetic Co grains from the Cu. In another example, an amorphous metal alloy film is produced whose Curie temperature is selected to be below room temperature. In this example, the amorphous film is annealed to produce crystalline granular precipitates whose Curie temperatures are above room temperature and that display the required superparamagnetic behavior.

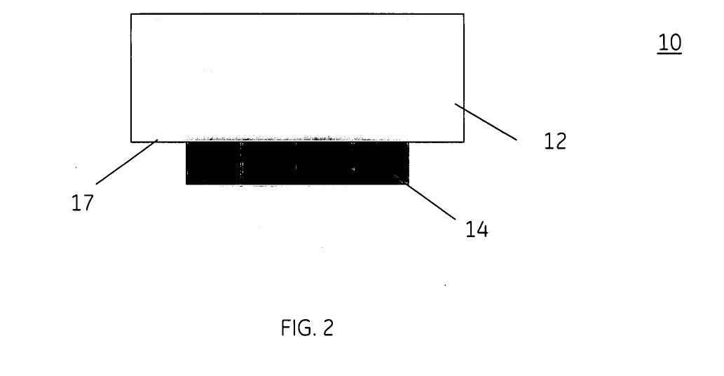

Returning now to the general description of the functional block 10, although the magnetic film 14 may be coextensive with the element 12, as depicted in FIG. 1, in other embodiments, the magnetic film is patterned and includes at least one magnetic region. FIG. 2 schematically illustrates a functional block 10 with a patterned magnetic film 14. The magnetic film may be patterned into one or more regions. For the example shown in FIG. 3, the magnetic region is annular. As used here, the annular region is ring-shaped with either circular or more general elliptical symmetry.

Although FIGS. 1, 2 and 5 depict elements 12 with flat connecting surfaces 17, the elements 12 may also have a curved connecting surface 17 (not shown). For example, the connecting surface 17 may be concave, convex or ruffled.

The present invention can be used with a wide variety of elements 12, and exemplary elements 12 include without limitation semiconductor devices, passive elements, photonic band-gap elements, luminescent materials, sensors, micro-electrical mechanical systems (MEMS) and energy harvesting devices (such as photovoltaic cells). As used here, the term “passive element” should be understood to refer to passive circuit elements, non-limiting examples of which include resistors, capacitors, inductors, and diodes. Exemplary semiconductor devices 12 include, without limitation, transistors, diodes, logic gates, amplifiers and memory circuits. Examples of transistors include, without limitation, field effect transistors (FETs), MOSFETs, MISFETs, IGBTs, bipolar transistors and J-FETs. The semiconductor devices may for example comprise Si, GaN, GaAs, InP, SiC, SiGe or other semiconductors.

A functional block 10 may include a single element 12 or a group of elements 12. A group of elements 12 for a functional block 10 may include different types of elements. For example, a functional block may comprise multiple transistors configured as a digital logic gate or an analog amplifier.

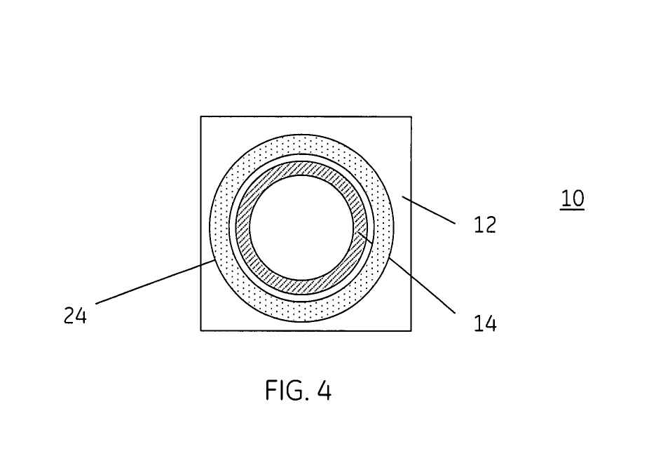

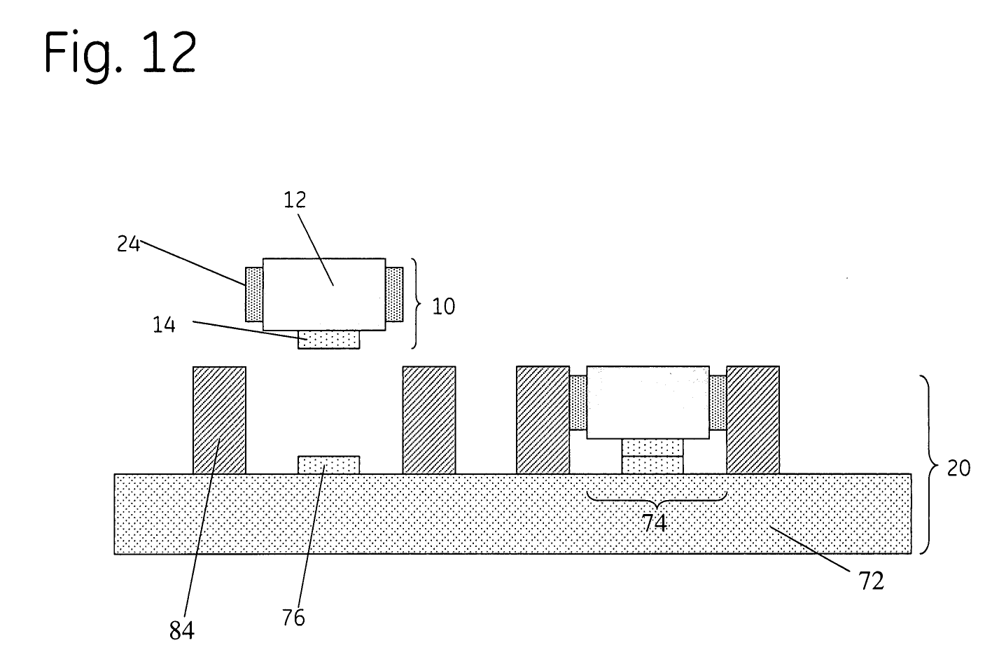

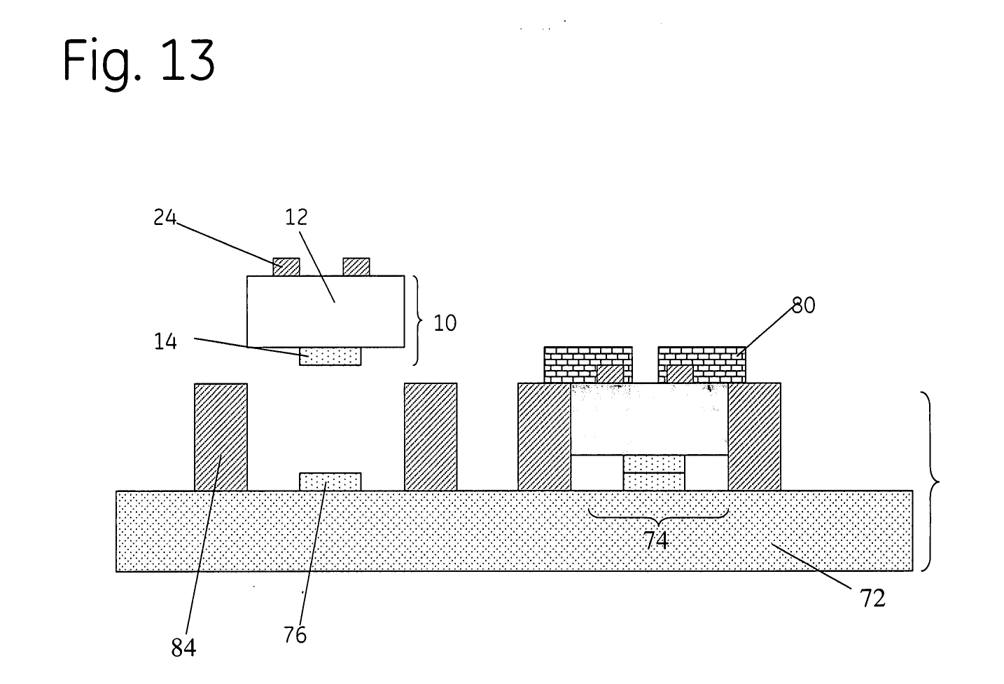

Many of these elements 12, such as semiconductor devices, require electrical contacts. For many embodiments, the functional block 10 further includes at least one electrical contact 24 for each of the elements 12, as shown for example in FIGS. 3 and 4. The contacts are formed of conductive materials, non-limiting examples of which include gold, platinum, nickel, copper, aluminum, titanium, tungsten, tantalum, molybdenum and alloys. In addition the contact may contain a soldering material. Non-limiting examples include alloys of Pb, Sn, Bi, In, Ag, Au, Cd, Zn and Ga. The solder may be deposited on a gold or other conductive film, for example, forming a layered structure. The solder may be deposited on the electrical contacts 24 to the functional blocks 10 and/or deposited on the article 20. The contacts to the blocks may be located on the same surface as the magnetic material as shown in FIG. 4. Alternatively, the contacts to the blocks may be on the side of the block as shown in FIG. 12 and/or on the opposite side of the magnetic material 14 as shown in FIG. 13. If opposite side contacts are used, a bridging metallization layer 80 may be used to make electrical connection to the blocks as shown in FIG. 13. The contacts 24 can be configured as desired. For example, for the exemplary embodiment shown in FIG. 3, the patterned magnetic region 14 is ring-shaped, and the electrical contact 24 is a circular contact 24 disposed within the ring shaped magnetic region 14. For the exemplary embodiment illustrated in FIG. 4, the electrical contact 24 is a ring shaped contact concentrically arranged about a ring-shaped magnetic region. In other embodiments with circular symmetry, the patterned magnetic region 14 is circular, and the electrical contacts 24 are formed as one or more rings centered on the magnetic region. By using contacts with circular symmetry, magnetic regions can be utilized with circular symmetry. As used here, the regions and contacts need not have perfect circular or annular symmetry but should be understood to encompass more general elliptical symmetries. Alternatively, if the magnetic regions are not symmetric (not shown), the contacts 24 do not require circular (or more general elliptical) symmetry.

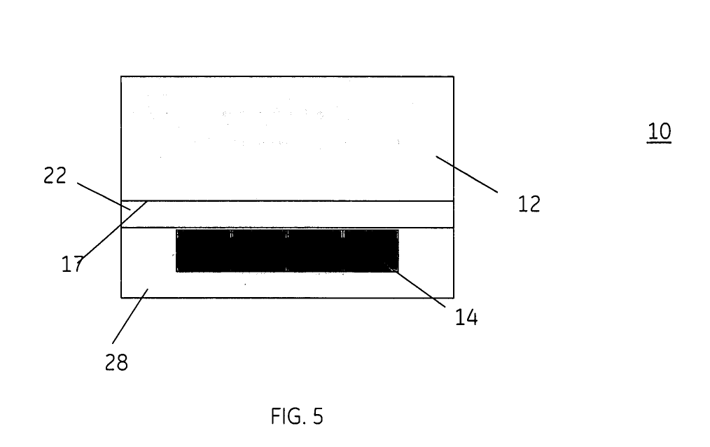

As shown, for example, in FIG. 5, for particular embodiments, the functional block 10 further includes a protective layer 22 configured to protect the functional block 12. For the exemplary configuration shown in FIG. 5, the protective layer 22 is formed over portions of element 12. The protective layer 22 can be organic or inorganic, and example materials for the protective layer 22 include, without limitation, Si₃N₄ (silicon nitride), SiO₂ (silicon dioxide), polyimide, BCP and paraylene. Polyimide is an organic polymer, examples of which include materials marketed under the trade names Kapton® and Upilex®. Upilex® is commercially available from UBE Industries, Ltd., and Kapton® is commercially available from E. I. du Pont de Nemours and Company. Other exemplary flexible organic polymers include polyethersulfone (PES) from BASF, polyethyleneterephthalate (PET or polyester) from E. I. du Pont de Nemours and Company, polyethylenenaphthalate (PEN) from E. I. du Pont de Nemours and Company, and polyetherimide (PEI) from General Electric.

As discussed above, solder is used for certain embodiments to fasten the functional blocks 10 to the article 20 after assembly. For other embodiments, the functional block 10 further includes an activated adhesive 28 attached to the functional block 10 and configured to fasten the functional block 10 to an article 20 after assembly of the functional block to the article and upon activation. One example use of the activated adhesive is depicted in FIG. 5. The adhesive 28 may be attached directly or indirectly to the element 12. Examples of activated adhesives 28 include, without limitation, photopolymerizable acrylate adhesives. Depending on the adhesive used, the activation may comprise application of ultraviolet light or thermal activation, for example. Other adhesives may be chemically activated.

An article 20 embodiment of the invention is described with reference to FIGS. 6-10. The article 20 is configured for the magnetically directed self-assembly (MDSA) of a number of functional blocks 10, as illustrated, for example in FIG. 6.

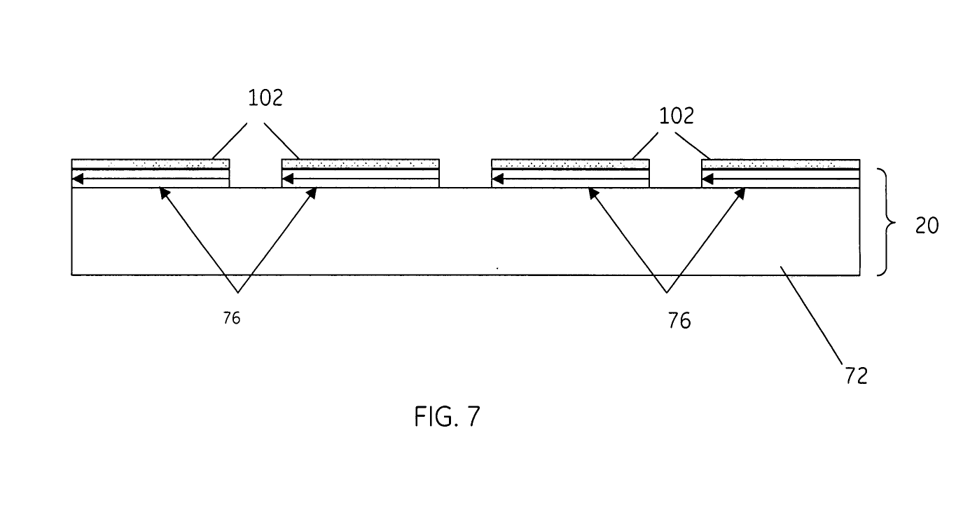

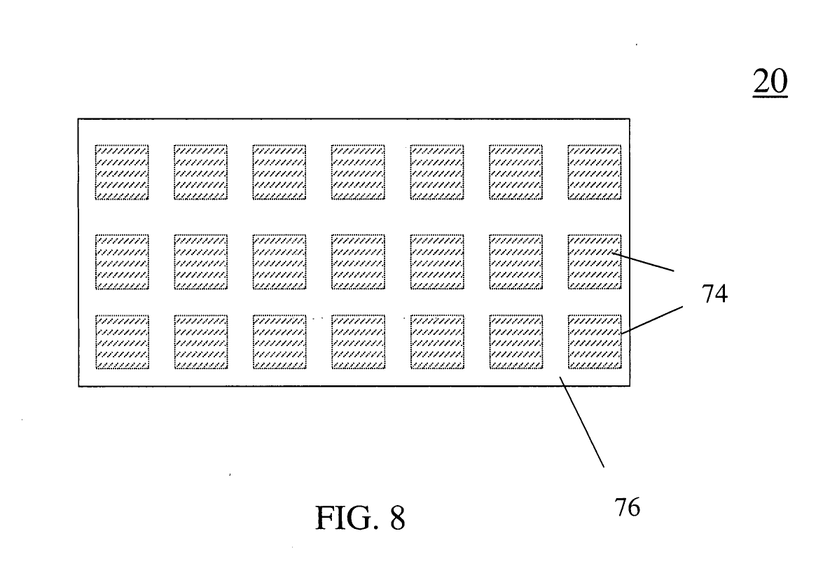

As shown for example in FIGS. 6 and 7, the article 20 includes a substrate 72 and a patterned magnetic film 76 disposed on the substrate 72 and defining at least one receptor site 74. FIG. 8 is a top view of an example arrangement of receptor sites for an article. This arrangement is merely illustrative. The patterned magnetic film 76 is magnetized in a longitudinal direction. More generally, the patterned magnetic film 76 is magnetized primarily in a longitudinal direction As used herein, the term “film” refers to a structure having one or more layers. As used here, longitudinal magnetization refers to a film with a remnant magnetization in a direction substantially parallel to the plane of the article 20. For most geometries, the thickness of the magnetic films 76 is substantially less than the typical in-plane dimension. In this case, shape anisotropy causes the magnetic moment to align preferentially in plane. However if the thickness of the magnetic film 76 is comparable to or larger than the typical in-plane dimension, a hard magnetic material may be used. The hard magnetic material may be anisotropic with an in-plane easy axis or isotropic but with a large enough coercive field to overcome demagnetization fields.

As a non-limiting example, the magnetic film 76 may comprise a hard magnetic powder embedded in a polymer binder. Non-limiting examples of hard magnetic powders include Strontium ferrite, Barium ferrite, Nd₂Fe₁₄B, SmCo₅, Sm₂Co₁₇, TbFe₂, Sm₂Fe₁₇Nₓ, Alnico, CoPt alloys, FePt alloys, CoPd alloys, and FePd alloys. A non-limiting example of a polymer binder is a thermosetting plastic, for example PI-2555 polyimide resin from HD Microsystems. The compound may also contain additional dispersants to reduce particle agglomeration and/or adhesion promoters as is known in the art. The compound may be applied to the substrate using a variety of different techniques as is known in the art. Non-limiting examples include, spin-coating, stencil printing, screen printing and gravure printing. The polymer binder may then be cured using techniques well-known in the art. For example, a thermosetting resin such as PI-2555 from HD Microsystems is heated to about 250 C. for several hours to cure. If the magnetic powder is anisotropic, a longitudinal magnetic field may be applied during curing to align the particle easy axis in the longitudinal direction. Depending upon the application technique, the magnetic film may be further patterned using photolithographic techniques or laser ablation, for example, as is known in the art. A longitudinal magnetic field is then applied to the magnetic film 76 to magnetize. For full binding strength, the magnetic field strength should be high enough to saturate the magnetization of the magnetic film 76 in the longitudinal direction.

In an alternative embodiment, the magnetic film may be deposited using traditional thin film deposition techniques such as sputtering, evaporation, chemical vapor deposition and electroplating. Non-limiting examples of thin materials include CoPt alloys, FePt alloys, CoPd alloys, FePd alloys and CoCrPt alloys. The film is then patterned into the desired geometry using conventional photolithographic techniques and/or laser ablation. A longitudinal magnetic field is then applied to the magnetic film 76 to magnetize the film 76. For full binding strength, the magnetic field strength should be high enough to saturate the magnetization of the magnetic film 76 in the longitudinal direction.

In particular embodiments, the patterned magnetic film 76 comprises a hard magnetic material characterized by a maximum BH product of greater than about 1 MGOe. Beneficially, the patterned magnetic film 76 comprises a magnetic material characterized by a maximum BH product of greater than about 10 MGOe.

The magnetic film may be patterned to be void of magnetic material (air gaps) in the receptor site or may be patterned to remove some but not all of the magnetic film in the receptor site. For the illustrated embodiments, these gaps (either partial or complete) serve as the receptor sites.

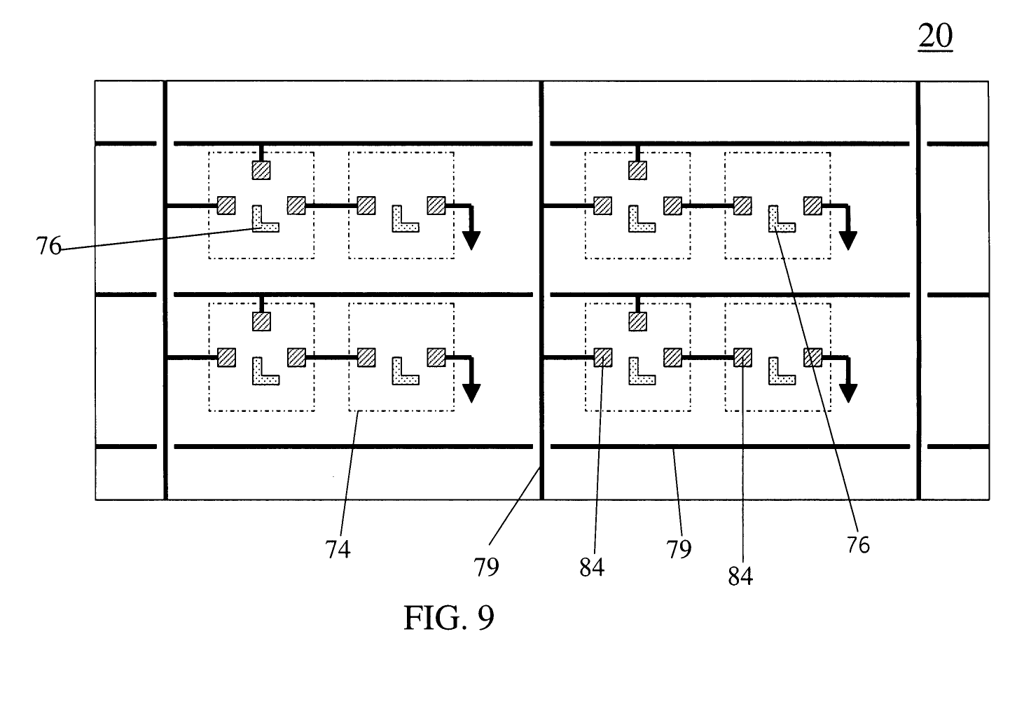

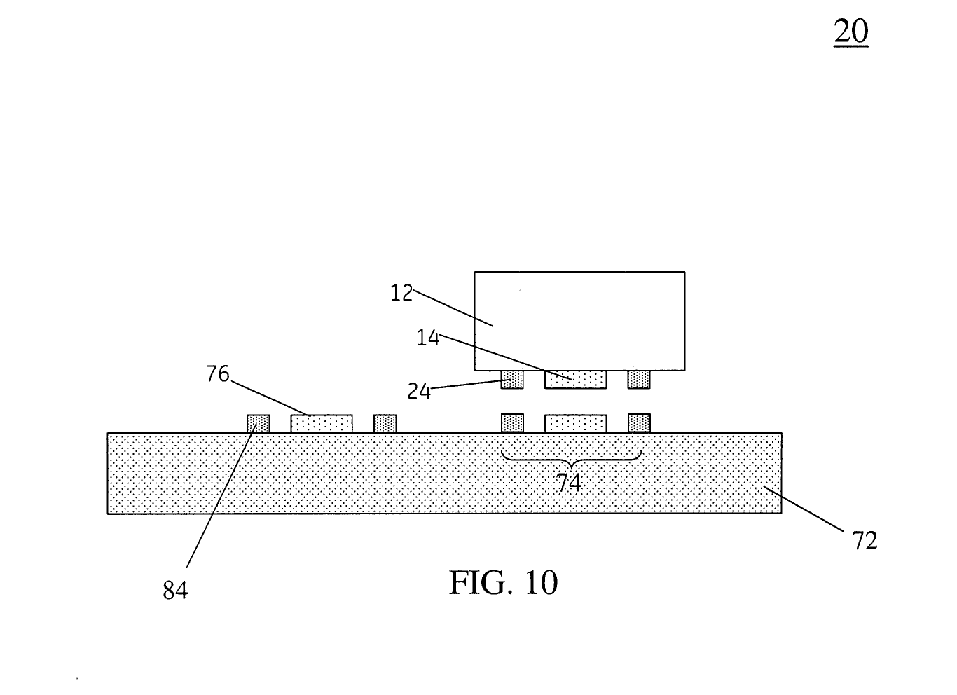

In order to provide electrical connections between receptor sites 74 for the respective functional blocks 10, for certain embodiments the article 20 further includes at least one interconnect layer 79 attached to the substrate 72, as schematically depicted in FIGS. 9 and 10, for example. FIG. 9 is a top view of an interconnect layer 78 and as shown, includes a number of electrical contacts 84 for interconnecting the functional blocks 10 to be assembled at the receptor sites 74. FIG. 10 is a side view of the article 20. Connections 79 can be formed of a variety of conductive materials, non-limiting examples of which include copper, gold and alloys thereof. Exemplary, non-limiting, interconnect layers include Copper on Kapton® and Gold on Kapton®.

Depending on the application, the receptor sites may be recessed within the substrate or may be level with the substrate 72. In particular embodiments, one or more of the receptor sites are recessed and/or are level with the substrate. Further, the receptor sites 74 may be shaped. The receptor sites 74 may also be embossed within the substrate 72.

The substrate 72 may take many forms. For particular embodiments, the substrate 72 is flexible. In one non-limiting example, the flexible substrate 72 comprises polyimide. Other non-limiting examples include polycarbonate, liquid-crystal polymer and polyetherimide. According to a particular embodiment, the substrate comprises a sheet of a flexible material, such as polyimide. Such flexible substrates desirably lend themselves to low-cost manufacture of the assembly 20 using roll-to-roll fabrication techniques. Roll-to-roll fabrication techniques employ a variety of processes, non-limiting examples of which include gravure printing, flexo printing, ink jet printing, screen printing and offset printing. Other roll-to-roll fabrication processes utilize processes adapted from traditional batch processes such as photolithography, sputtering and wet chemical etching. Other benefits to the use of flexible substrates 72 include providing a robust article 20, as compared to conventional articles formed on rigid silicon or glass substrates, for example.

For other applications, the substrate 72 may be rigid, non-limiting examples of which include silicon and glass. In addition to being applicable to a wide variety of substrate materials, the substrate may have a variety of geometries and shapes. For example, for certain embodiments, the substrate 72 is a curved, rigid object, non-limiting examples of which include, for example, turbine blades and aircraft fuselages.

Although FIGS. 6 and 7 show a patterned magnetic film 76 deposited on the substrate 72, the patterned magnetic film 76 may also be deposited on or otherwise affixed to an intermediate layer (not shown), such as a moisture and oxygen barrier layer, formed on the substrate 72. The patterned magnetic film 76 may be deposited on or other affixed to contacts formed on the substrate 72. Moreover, the term “deposited” also encompasses patterned magnetic films 76 that are partially or fully embedded in the substrate 72 (not shown).

Returning now to the general description of the article, for certain embodiments, the patterned magnetic film 76 has a thickness greater than about 0.2 microns. In more particular embodiments, the patterned magnetic film 76 has a thickness greater than about 1 micron. In other embodiments, the thickness of the patterned magnetic film 76 is greater than about 5 microns, and for particular embodiments the thickness of the patterned magnetic film 76 is in a range of about 5-100 microns. The thickness of the patterned magnetic film depends upon the BH product for the patented magnetic film 76, as well as the block size for the functional blocks 10 being assembled to the article 20.

The article further optionally includes a soft magnetic screening layer 102 disposed on the patterned magnetic film 76, as shown for example in FIG. 7. Beneficially, the soft magnetic screening layer 102 screens the background magnetic field, so that each receptor site 74 sees mainly the field gradients originating at that receptor site. Non-limiting examples of soft magnetic materials for the screening layer 102 include Fe₃O₄, γ-Fe₂O₃, Ni₈₀Fe₂₀, NiFe₂O₄, MnFe₂O₄, MnZn ferrite, NiZn ferrite, Ni, Fe and combinations thereof.

A method of manufacture for the functional blocks is provided. The method includes forming a magnetic film on a host substrate having an array of elements, where the magnetic film has a magnetic remanence (M_{R}/M_{S}) of less than about 0.2, a coercive field (H_{c}) of less than about 100 Oersteds (100 Oe) and a permeability (μ) of greater than about 2. To determine the magnetic remanence and coercivity (H_{c}) for a given material, the material may be deposited on a substrate and patterned into a geometry wherein the thickness is small compared to the smallest lateral dimension so that demagnetization effects are negligible. A hysteresis sweep is then performed in the sample in an applied magnetic field substantially parallel to the lateral direction. The sweep must be large enough such that at the largest magnetic fields, no hysteresis is evident. The ratio of the magnetization in zero-field (M_{R}) to the magnetization at saturation (M_{S}) is then the magnetic remanence. The field at which the magnetization switches from positive to negative is defined as the coercivity (H_{c}). The magnetic film may be formed using a variety of techniques, non-limiting examples of which include stencil printing, screen printing, gravure printing, ink-jet printing, electron beam evaporation, sputtering, resistive source evaporation, electroplating and spin coating. The magnetic film may be affixed to the elements or to an intermediate layer (not shown), such as SiO₂ or Si₃N₄, formed on the elements. The method further optionally includes forming the elements on the host substrate prior to formation of the magnetic film, where the elements are selected from the group consisting of semiconductor devices, passive elements, photonic bandgap elements, luminescent elements, sensors, micro-electrical mechanical systems (MEMSs), energy harvesting devices and combinations thereof.

The method further optionally includes forming electrical contacts to the elements on the host substrate prior to formation of the magnetic film. Example electrical contacts 24, 84 are discussed above with reference to FIGS. 3 and 4. The contacts are formed of conductive materials, non-limiting examples of which include gold, platinum, nickel, copper, aluminum, titanium, tungsten, tantalum, molybdenum and alloys. The electrical contacts 24, 84 can be configured as desired. The electrical contact may also include a solder layer for low resistance electrical contacts.

The method further optionally includes patterning the magnetic film to form the magnetic regions, such that at least one of the magnetic regions is provided for a respective group comprising at least one of the elements. The magnetic film may be patterned using a variety of techniques, non-limiting examples of which include photolithography, laser ablation, and employing masks during the deposition of the films. Example patterned magnetic films 14 are discussed above with reference to FIG. 2.

A method of forming an article for assembly is provided. The method includes depositing a magnetic film on a substrate, where the magnetic film is characterized by a maximum BH product of greater than about 1 MGOe. A variety of deposition techniques can be used to form the magnetic film, non-limiting examples of which include stencil printing, screen printing, gravure printing, ink-jet printing, electron beam evaporation, sputtering, resistive source evaporation, electroplating and spin coating. The method further includes patterning the magnetic film to form at least one receptor site. A variety of techniques can be used to pattern the magnetic film, non-limiting examples of which include photolithography and laser ablation. The method further includes magnetizing the magnetic film such that the magnetic film has a longitudinal magnetic anisotropy.

For particular embodiments, the magnetic film comprises at least one material selected from the group consisting of samarium iron nitride, neodymium iron boride, samarium cobalt, barium ferrite, strontium ferrite, cobalt platinum alloy, cobalt palladium alloy and combinations thereof.

The method further optionally includes depositing a soft magnetic screening layer on the magnetic film. The screening layer is discussed above with reference to FIG. 7. Non-limiting examples of materials for the soft magnetic screening layer include Fe₃O₄, γ-Fe₂O₃, Ni₈₀Fe₂₀, NiFe₂O₄, MnFe₂O₄, MnZn ferrite, NiZn ferrite, Ni, Fe and combinations thereof. A variety of deposition techniques can be used to deposit the soft magnetic screening layer on the magnetic film, non-limiting examples of which include stencil printing, screen printing, gravure printing, ink-jet printing, electron beam evaporation, sputtering, resistive source evaporation, electroplating and spin coating.

An assembly embodiment of the invention is described generally with reference to FIG. 6, which depicts a partially assembled assembly 30. As shown for example in FIG. 6, assembly 30 includes at least one functional block 10. The functional block 10 includes at least one element 12, and a magnetic film 14 attached to the element 12 and having a magnetic remanence (M_{R}/M_{S}) of less than about 0.2, a coercive field (H_{c}) of less than about 100 Oersteds (100 Oe) and a permeability (μ) of greater than about 2, as discussed above with reference to FIG. 1. Various aspects of the functional blocks 10 are discussed above with reference to FIGS. 1-5. The assembly 30 further includes an article comprising a substrate, where the substrate has at least one receptor site 74 for assembling a respective one of the functional blocks 10. Various aspects of the article 20 are discussed above with reference to FIGS. 6-10.

FIG. 6 illustrates an exemplary assembly process. Initially, the magnetic films 14 in the functional blocks 10 are demagnetized (far left). As a block 10 approaches a receptor site 74, the magnetic film 14 for that block is partially magnetized by the local longitudinal magnetic fields at the receptor site. Upon assembly (far right), the magnetic film 14 is magnetized.

Many of the elements 12, such as the semiconductor devices, require electrical contacts. For many embodiments, the assembly 30 further includes at least one electrical contact 24, 84 for at least one of the elements 12. The electrical contacts 24, 84 may be formed on the functional block 10 and/or on the article 20. For the exemplary embodiments shown in FIGS. 3 and 4, electrical contacts 24 are formed on functional blocks 10. For the exemplary embodiment depicted in FIGS. 9 and 10, electrical contacts 84 are formed on the article 20. For the embodiment shown in FIG. 10, the contacts 84 are front contacts. Side and back contacts (not shown) may also be employed. Connections 79 may also be employed in the article 20, as shown for example in FIG. 9. For the exemplary embodiment illustrated in FIG. 9, the connections 79 are disposed in an interconnect layer 78.

After assembly, it is desirable to fasten the functional block 10 to the article 20, for example by solder or other fastening means. According to a particular embodiment, the at least one contact 24 is configured to fasten the functional block to an article 20 after assembly of the functional block to the article 20. Additional details of this embodiment are provided above in the description of the functional block embodiment.

For other embodiments, and as shown, for example, in FIG. 5, the assembly 30 further includes an activated adhesive 28 that fastens the functional block(s) 10 to the article 20. This embodiment is discussed above with reference to FIG. 5.

The assembly 30 is adapted for the magnetically directed self-assembly of electronic components. A variety of elements can be used, non-limiting examples of which include semiconductor devices, passive elements, photonic bandgap elements, luminescent materials, sensors, micro-electrical mechanical systems (MEMS), energy harvesting devices and combinations thereof. Non-limiting examples of semiconductor devices include transistors, diodes, logic gates, amplifiers and memory circuits. Non-limiting examples of passive elements include resistors, capacitors, inductors, and diodes. In many applications, a variety of elements 12 will be assembled, such that the assembly 30 is heterogeneous. For example, diodes and field effect transistors (FETs) may be used to form an x-ray panel.

Beneficially, the functional blocks 10 can be used to assemble to an article 20 to provide the performance benefits of high-performance electronics (for example, single-crystal FETs) at a low cost for the larger article 20. Because the elements are formed in a separate process and assembled to the article 20, there is no upper limit on the size of the article 20. Further, because the cost per unit-area of assembled substrate is dictated by the density of functional blocks 10 and the cost of the article 20, by utilizing small-area functional blocks 10, high quality electronics can be assembled to large area articles (for example 10 m×10 m) at relatively low cost.

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A functional block for assembly comprising:
at least one element; and
a magnetic film attached to the element and having a magnetic remanence (M_{R}/M_{S}) of less than about 0.2, having a coercive field (H_{c}) of less than about 100 Oersteds (100 Oe) and having a permeability (μ) of greater than about two (2),
wherein at least one of the at least one element is selected from the group consisting of a semiconductor device, a passive element, a photonic bandgap element, a luminescent material, a sensor, a micro-electrical mechanical system (MEMS), an energy harvesting device and combinations thereof.

2. The functional block of claim 1, wherein the magnetic remanence (M_{R}/M_{S}) is less than about 0.1.

3. The functional block of claim 1, wherein the magnetic film comprises a superparamagnetic material.

4. The functional block of claim 1, wherein the permeability (μ) is greater than about ten (10).

5. The functional block of claim 1, wherein the magnetic film is patterned and comprises at least one magnetic region.

6. The functional block of claim 1, further comprising at least one electrical contact for each of the at least one element.

7. The functional block of claim 1, wherein the element comprises a semiconductor device selected from the group consisting of transistors, diodes, logic gates, amplifiers and memory circuits.

8. The functional block of claim 1, wherein the element comprises a passive element selected from the group consisting of resistors, capacitors, inductors, and diodes.

9. The functional block of claim 1, wherein the magnetic film comprises a magnetic material selected from the group consisting of Fe₃O₄, γ-Fe₂O₃, Ni₈₀Fe₂₀, NiFe₂O₄, MnFe₂O₄, MnZn ferrite, NiZn ferrite, Ni, Fe and combinations thereof.

10. The functional block of claim 1, wherein the magnetic film comprises a plurality of superparamagnetic nanoparticles embedded in a polymer binder.

11. The functional block of claim 1, wherein the magnetic film comprises at least one surface that is textured to generate a perpendicular anisotropy.

12. An article for assembly comprising:
a substrate; and
a patterned magnetic film disposed on the substrate and defining at least one receptor site, wherein the patterned magnetic film is magnetized primarily in a longitudinal direction and is characterized by a BH product of greater than about 1 megaGauss Oe.

13. The article of claim 12, wherein the patterned magnetic film comprises at least one material selected from the group consisting of samarium iron nitride, neodymium iron boride, samarium cobalt, barium ferrite, strontium ferrite, cobalt platinum alloy, cobalt palladium alloy and combinations thereof.

14. The article of claim 12 further comprising a soft magnetic screening layer disposed on the patterned magnetic film.

15. The article of claim 14, wherein the soft magnetic screening layer comprises a material selected from the group consisting of Fe₃O₄, γ-Fe₂O₃, Ni₈₀Fe₂₀, NiFe₂O₄, MnFe₂O₄, MnZn ferrite, NiZn ferrite, Ni, Fe and combinations thereof.

16. The article of claim 12, wherein the patterned magnetic film comprises a hard magnetic powder dispersed in a polymer binder.

17. The article of claim 16, wherein the hard magnetic powder is selected from the group consisting of Strontium ferrite, Barium ferrite, Nd₂Fe₁₄B, SmCo₅, Sm₂Co₁₇, TbFe₂, Sm₂Fe₁₇Nₓ, Alnico, CoPt alloys, FePt alloys, CoPd alloys, FePd alloys and combinations thereof.

18. A method of manufacture comprising:
forming a magnetic film on a host substrate having an array of elements, wherein the magnetic film has a magnetic remanence (M_{R}/M_{S}) of less than about 0.2, has a coercive field (H_{c}) of less than about 100 Oersteds (100 Oe) and has a permeability (μ) of greater than about 2.

19. The method of claim 18, further comprising forming the elements on the host substrate prior to the forming the magnetic film step, wherein the elements are selected from the group consisting of semiconductor devices, passive elements, photonic bandgap elements, luminescent elements, sensors, micro-electrical mechanical systems (MEMSs), energy harvesting devices and combinations thereof.

20. The method of claim 19, further comprising forming a plurality of electrical contacts to the elements on the host substrate prior to the forming the magnetic film step.

21. The method of claim 18, further comprising patterning the magnetic film to form the magnetic regions, wherein the patterning step provides at least one of the magnetic regions for a respective group comprising at least one of the elements.

22. The method of claim 18, wherein the magnetic film comprises a material selected from the group consisting of Fe₃O₄, γ-Fe₂O₃, Ni₈₀Fe₂₀, NiFe₂O₄, MnFe₂O₄, MnZn ferrite, NiZn ferrite, Ni, Fe and combinations thereof.

23. The method of claim 18, wherein forming the magnetic film comprises embedding a plurality of superparamagnetic nanoparticles in a polymer binder.

24. The method of claim 18, wherein the receptor site comprises a gap in the patterned magnetic film.

25. A method of forming an article for assembly, the method comprising:
disposing a magnetic film on a substrate, wherein the magnetic film is characterized by a BH product of greater than about 1 megaGauss Oe;
patterning the magnetic film to form at least one receptor site; and
magnetizing the magnetic film such that the magnetic film has a longitudinal magnetic anisotropy.

26. The method of claim 25, wherein the magnetic film comprises at least one material selected from the group consisting of Strontium ferrite, Barium ferrite, Nd₂Fe₁₄, SmCo₅, Sm₂Co₁₇, TbFe₂, Sm₂Fe₁₇Nₓ, Alnico, Cobalt Platinum alloys, Cobalt Palladium alloys, Iron Platinum alloys, Iron Palladium alloys, Cobalt Chromium Platinum alloys and combinations thereof.

27. The method of claim 25, further comprising disposing a soft magnetic screening layer on the magnetic film.

28. An assembly comprising:
at least one functional block comprising:
at least one element selected from the group consisting of a semiconductor device, a passive element, a photonic bandgap element,
a luminescent material, a sensor, a micro-electrical mechanical system (MEMS), an energy harvesting device and combinations thereof, and
a magnetic film attached to the element and having a magnetic remanence (M_{R}/M_{S}) of less than about 0.2, a coercive field (H_{c}) of less than about 100 Oersteds (100 Oe) and a permeability (μ) of greater than about 2; and
an article comprising a substrate, wherein the substrate has at least one receptor site for assembling a respective one of the at least one functional block.

29. The assembly of claim 28, wherein the at least one receptor site is disposed on the substrate, wherein the article further comprises at least one receptor configured to generate a magnetic field gradient for attracting the magnetic film, and wherein the at least one receptor is positioned at the receptor site.

30. The assembly of claim 28, wherein the article further comprises a patterned magnetic film disposed on the substrate and defining at least one receptor site, wherein the patterned magnetic film has a longitudinal magnetic anisotropy.

31. The assembly of claim 30, wherein the patterned magnetic film is characterized by a BH product of greater than about 1 megagauss Oe.

32. The assembly of claim 30, wherein the patterned magnetic film comprises a hard magnetic powder embedded in a polymer binder, wherein the magnetic powder comprises at least one material selected from the group consisting of Strontium ferrite, Barium ferrite, Nd₂Fe₁₄B, SmCo₅, Sm₂Co₁₇, TbFe₂, Sm₂Fe₁₇Nₓ, Alnico, Cobalt platinum alloys, Cobalt palladium alloys, iron platinum alloys, iron palladium alloys and cobalt chromium platinum alloys and combinations thereof.

33. The assembly of claim 30, further comprising a soft magnetic screening layer disposed on the patterned magnetic film.

34. The assembly of claim 28, wherein the magnetic remanence (B_{R}/B_{S}) of the magnetic film of the at least one functional block is less than about 0.1.

35. The assembly of claim 28, wherein the permeability (μ) of the magnetic film of the at least one functional block is greater than about ten (10).

36. The assembly of claim 28, wherein the magnetic film of the at least one functional block is patterned and comprises at least one magnetic region.

37. The assembly of claim 28, further comprising at least one electrical contact for the element.

38. The assembly of claim 28, wherein the at least one electrical contact fastens the functional block to the article.

39. The assembly of claim 28, further comprising an activated adhesive that fastens the functional block to the article.
